(19) United States
(12) Patent Application Publication
(10) Pub. No.: US 2026/0307119 A1
(43) Pub. Date: Oct. 8, 2026

(54) BOWL ASSEMBLY AND SUBSTRATE PROCESSING APPARATUS COMPRISING THE SAME

(71) Applicants: SEMES CO., LTD., Cheonan-si (KR); Samsung Electronics Co., Ltd., Suwon-si (KR)

(72) Inventors: Hwi Jun KIM, Cheonan-si (KR); Yong Beom JU, Cheonan-si (KR); Hyeon Jun LEE, Cheonan-si (KR); Jun Kil HWANG, Yongin-si (KR); Min Jae SON, Suwon-si (KR); Yong Sung KIM, Suwon-si (KR); Hyun Wook LEE, Suwon-si (KR); Il Gon CHOI, Suwon-si (KR)

(21) Appl. No.: 19/298,010

(22) Filed: Aug. 12, 2025

(30) Foreign Application Priority Data
Apr. 7, 2025 (KR) 10-2025-0044487

(51) Int. Cl. B08B 15/02; H01L 21/67

(52) U.S. Cl. CPC B08B 15/02; H10P 72/0414

(57) ABSTRACT

A bowl assembly is provided in which fume generation can be reduced. The bowl assembly comprises a first bowl provided to surround a substrate support unit supporting a substrate processed with a processing liquid, a second bowl provided to surround the first bowl, and a third bowl provided to surround the second bowl, wherein each of the first bowl, the second bowl and the third bowl is provided with an upper wall that is provided to be inclined upward in a direction toward the substrate support unit, the upper walls include a first upper wall of the first bowl, a second upper wall of the second bowl, and a third upper wall of the third bowl, and each of the first upper wall, the second upper wall, and the third upper wall has an edge, and any one of the first upper wall, the second upper wall and the third upper wall has a structure that is widened toward its edge from a portion adjacent to its edge.

### CROSS-REFERENCE TO RELATED APPLICATION

This application claims priority to Korean Patent Application No. 10-2025-0044487 filed on Apr. 7, 2025 in the Korean Intellectual Property Office and all the benefits accruing therefrom under 35 U.S.C. 119, the contents of which in its entirety are herein incorporated by reference.

### BACKGROUND

### Technical Field

The present disclosure relates to a bowl assembly and a substrate processing apparatus comprising the same.

### Description of the Related Art

Contaminants, such as particles, organic contaminants, or metal contaminants, which remain on a surface of a substrate, significantly affect properties and production yield of semiconductor devices. Therefore, a cleaning process for removing various contaminants attached to the surface of the substrate is important in a semiconductor manufacturing process.

The cleaning process may be performed before and after each unit process of manufacturing a semiconductor. The cleaning process may include a process of removing contaminants remaining on the substrate by using a cleaning solution, removing the cleaning solution remaining on the substrate by using pure water, and/or drying the substrate by using an organic solvent, a supercritical fluid, or nitrogen gas.

This cleaning process may be performed by supplying a processing liquid (cleaning solution, pure water, supercritical fluid, and/or nitrogen gas) to the substrate while rotating the substrate in a spin type method. That is, after the substrate is fixed to a substrate support unit capable of supporting the substrate, the processing liquid is supplied to the substrate through a nozzle as the substrate support unit on which the substrate is placed rotates, so that the processing liquid spreads to an entire surface of the substrate by a centrifugal force.

In addition, in the cleaning process, gas (referred to as fume) is generated by evaporation of the processing liquid as the processing liquid is used, and this gas should be discharged along an airflow flowing in a chamber for the cleaning process, and when the gas is not discharged, the inside of the chamber is contaminated. For example, when the gas re-inflows around the substrate, yield of the substrate may be deteriorated, so the airflow inside the chamber is important.

### BRIEF SUMMARY

An object of the present disclosure is to provide a bowl assembly and a substrate processing apparatus comprising the same, in which different processing liquids easily flow into different bowls separately and an airflow is formed in a dead zone where the airflow may be stagnated around the bowl, so that fume may be reduced.

The objects of the present disclosure are not limited to those mentioned above and additional objects of the present disclosure, which are not mentioned herein, will be clearly understood by those skilled in the art from the following description of the present disclosure.

According to one aspect of the present disclosure to achieve the above objects, a bowl assembly comprises a first bowl provided to surround a substrate support unit supporting a substrate processed with a processing liquid, a second bowl provided to surround the first bowl, and a third bowl provided to surround the second bowl, wherein each of the first bowl, the second bowl and the third bowl is provided with an upper wall that is provided to be inclined upward in a direction toward the substrate support unit, the upper walls include a first upper wall of the first bowl, a second upper wall of the second bowl, and a third upper wall of the third bowl, and each of the first upper wall, the second upper wall, and the third upper wall has an edge, and any one of the first upper wall, the second upper wall and the third upper wall has a structure that is widened toward its edge from a portion adjacent to its edge.

According to another aspect of the present disclosure to achieve the above objects, a substrate processing apparatus comprises a substrate support unit supporting a substrate; the bowl assembly; an elevation assembly ascending and descending the bowl assembly; and a fan filter unit forming an airflow from an upper portion toward a lower portion of the substrate support unit, wherein the elevation assembly includes: a first elevation unit ascending and descending the first bowl; a second elevation unit ascending and descending the second bowl; and a third elevation unit ascending and descending the third bowl.

According to still another aspect of the present disclosure to achieve the above objects, a bowl assembly comprises a first bowl provided to surround a substrate support unit supporting a substrate processed with a processing liquid; a second bowl provided to surround the first bowl; and a third bowl provided to surround the second bowl, wherein each of the first bowl, the second bowl and the third bowl is provided with an upper wall that is provided to be inclined upward in a direction toward the substrate support unit, the upper walls include a first upper wall of the first bowl, a second upper wall of the second bowl, and a third upper wall of the third bowl, the third upper wall has a gradient greater than that of the second upper wall so that it is widened from the second upper wall, and an edge of the second upper wall is bent downward to surround an edge of the first upper wall.

Details of the other embodiments are included in the detailed description and drawings.

The bowl assembly and the substrate processing apparatus comprising the same according to the present disclosure may improve processing and stability as different types of processing liquids easily flow into different bowls separately so that the processing liquids may be individually recovered/drained without being mixed.

In addition, in the present disclosure, since an airflow may be formed in a dead zone where the airflow may be stagnant around a bowl, fume may be discharged along the airflow to reduce the fume, whereby an environment in a chamber may be improved to improve yield of the substrate and reduce additional works such as bowl cleaning.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view illustrating a substrate processing system;

FIG. 2 is a view illustrating a substrate processing apparatus according to some embodiments of the present disclosure;

FIG. 3 is a view illustrating that a processing liquid is recovered in a substrate processing apparatus according to some embodiments of the present disclosure;

FIG. 4 is a view illustrating that a processing liquid is drained in a substrate processing apparatus according to some embodiments of the present disclosure;

FIG. 5 is a view illustrating a state that a fourth bowl of the substrate processing apparatus according to the first embodiment of the present disclosure is lifted;

FIG. 6 is a view illustrating a state that a third bowl of the substrate processing apparatus according to the first embodiment of the present disclosure is lifted;

FIG. 7 is a view illustrating a state that a second bowl of the substrate processing apparatus according to the first embodiment of the present disclosure is lifted;

FIG. 8 is a view illustrating an airflow that flows along an inner side of a third bowl as a processing liquid is recovered to a first bowl of the substrate processing apparatus according to the first embodiment of the present disclosure;

FIG. 9 is a view illustrating a region A of FIG. 8;

FIG. 10 is a view illustrating a bowl assembly of a substrate processing apparatus according to the second embodiment of the present disclosure;

FIG. 11 is a view illustrating a bowl assembly of a substrate processing apparatus according to the third embodiment of the present disclosure;

FIG. 12 is a view illustrating a bowl assembly of a substrate processing apparatus according to the fourth embodiment of the present disclosure; and

FIG. 13 is a view illustrating a substrate processing apparatus according to the fifth embodiment of the present disclosure.

### DETAILED DESCRIPTION OF THE DISCLOSURE

Hereinafter, the embodiments according to the present disclosure will be described in detail with reference to the accompanying drawings. The same reference numerals will be used for the same elements on the drawings and a redundant description of the corresponding elements will be omitted.

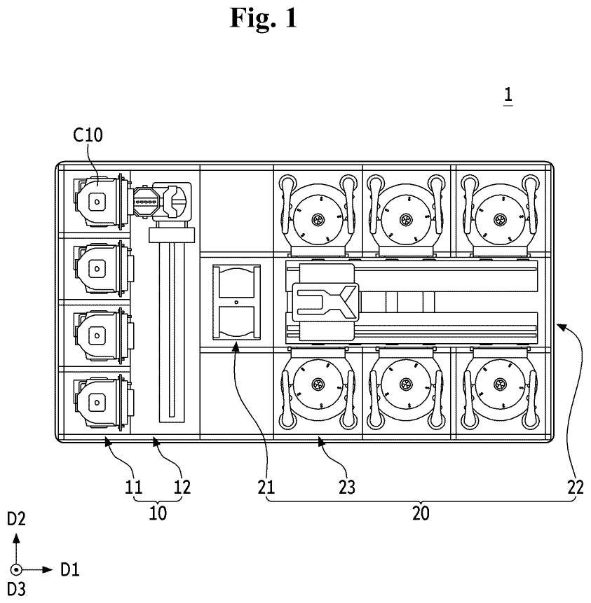

FIG. 1 is a plan view illustrating a substrate processing system.

Referring to FIG. 1, a substrate processing system 1 may include an index module 10 and a process processing module 20.

The index module 10 may include a load port 11 and a transfer frame 12. The load port 11, the transfer frame 12, and the processing module 20 may be sequentially arranged.

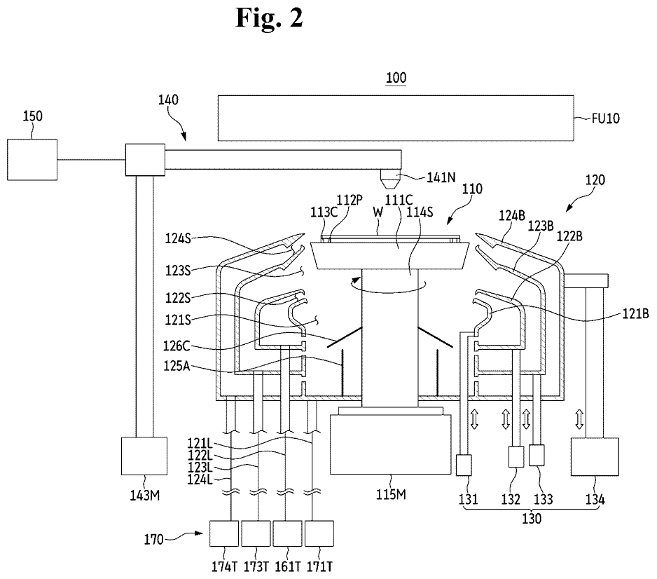

A container C10 in which a substrate W (see FIG. 2) is accommodated may be mounted on the load port 11. The load port 11 may be provided as a plurality of load ports, and the load ports may be arranged in a row along a second direction D2. Although four load ports 11 are provided as an example, the number of load ports 11 may increase or decrease depending on conditions such as process efficiency and footprint of the processing module 20.

The transfer frame 12 may transfer the substrate W between the container C10 seated on the load port 11 and a buffer unit 21. The transfer frame 12 may be provided with an index rail and an index robot.

The process processing module 20 may include a buffer unit 21, a transfer chamber 22, and a process chamber 23. A longitudinal direction of the transfer chamber 22 may be disposed parallel with a first direction D1. The process chamber 23 may be disposed on each of one side and the other side of the transfer chamber 22 along the second direction D2.

The buffer unit 21 may be disposed between the transfer frame 12 and the transfer chamber 22. The buffer unit 21 may provide a space in which the substrate W stays before the substrate W is transferred between the transfer chamber 22 and the transfer frame 12.

The transfer chamber 22 may transfer the substrate W between the buffer unit 21 and the process chamber 23 and between the process chambers 23. The transfer chamber 22 may be provided with a guide rail and a main robot. The guide rail may be arranged such that its longitudinal direction is parallel with the first direction D1. The main robot may be installed on the guide rail to linearly move along the first direction D1 on the guide rail 242.

The process chamber 23 forms a space for processing a substrate, and may be provided as a plurality of process chambers in the longitudinal direction and/or a vertical direction of the transfer chamber 22. That is, the arrangement and number of the process chambers 20 may be set depending on conditions such as process efficiency and footprint of the process processing module 20.

A substrate processing apparatus 100 for processing the substrate W with a processing liquid may be provided in the process chamber 23. The substrate processing apparatuses 100 provided in each process chamber 23 may have different structures depending on types of processes to be performed.

Optionally, the substrate processing apparatus 100 in each process chamber 23 may have the same structure. The process chamber 23 is divided into a plurality of groups, and the substrate processing apparatuses 100 provided to the process chambers 23 belonging to the same group may have the same structure.

Hereinafter, the substrate processing apparatus 100 provided in the process chamber 23 will be described with reference to the drawings.

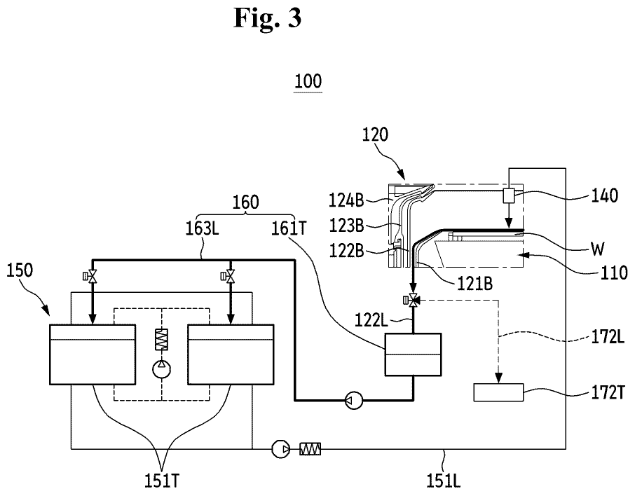

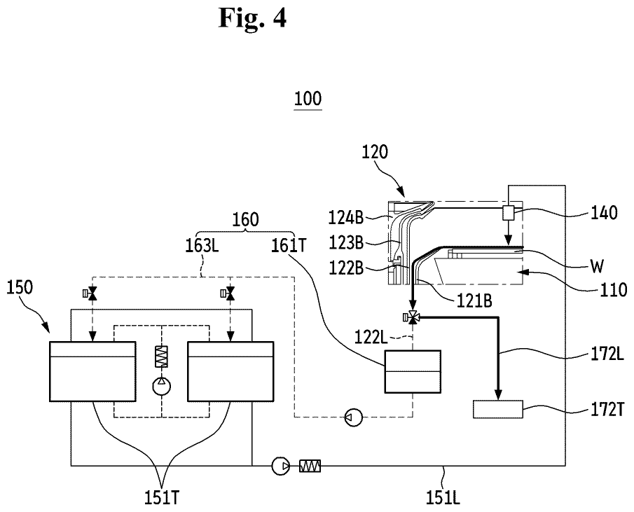

FIG. 2 is a view illustrating a substrate processing apparatus according to some embodiments of the present disclosure, FIG. 3 is a view illustrating that a processing liquid is recovered in a substrate processing apparatus according to some embodiments of the present disclosure, and FIG. 4 is a view illustrating that a processing liquid is drained in a substrate processing apparatus according to some embodiments of the present disclosure.

First, referring to FIG. 2, the substrate processing apparatus 100 may include a fan filter unit FU10, a substrate support unit 110, a bowl assembly 120, an elevation assembly 130, a spray unit 140, and a processing liquid supply unit 150.

The fan filter unit FU10 may be provided above the substrate support unit 110, and for example, may be installed above a housing of the process chamber 23. The fan filter unit FU10, in which a filter and an air supply fan are modularized into one unit, may filter clean air to generate a vertical airflow from an upper portion toward a lower portion of the substrate support unit 110 inside the process chamber 23.

The airflow formed by the fan filter unit FU10 may provide a uniform airflow to the upper portion of the substrate W, and contaminants such as fume generated in the process of processing the surface of the substrate W with a processing liquid are removed by being discharged to a first exhaust port 125A and/or a second exhaust port (e.g., it may be a fourth discharge line 124L in some embodiments) together with the air through the bowl assembly 120, so that cleanliness inside a processing space may be maintained.

The substrate support unit 110 may be disposed inside the bowl assembly 120. The substrate support unit 110 may support the substrate W and rotate the substrate W during the process. For example, the substrate support unit 110 may include a spin chuck 111C, a support pin 112P, a chuck pin 113C, and a support shaft 114S.

The spin chuck 111C may have a circular upper surface facing the substrate W. A support shaft 114S that can be rotated by a driving body 115M such as a motor may be coupled to a bottom surface of the spin chuck 111C.

The support pin 112P may be provided as a plurality of support pins in the spin chuck 111C. For example, the support pins 112P may be disposed to be spaced apart from each other by a predetermined interval at an edge portion of an upper surface of the spin chuck 111C and may be protruded upward from the spin chuck 111C.

The plurality of support pins 112P may be arranged to have an annular ring shape as a whole by their combination. The support pin 112P may support a rear edge of the substrate such that the substrate is spaced apart from the upper surface of the spin chuck 111C by a predetermined distance.

The chuck pin 113C may be provided as a plurality of chuck pins in the spin chuck 111C. The chuck pin 113C may be disposed to be farther from the center of the spin chuck 111C than the support pin 112P. The chuck pin 113C may be provided to be protruded upward from the spin chuck 111C. The chuck pin 113C may support the circumference of the substrate W so that the substrate is not detached from its regular position in a lateral direction when the spin chuck 111C is rotated.

The chuck pin 113C may be provided to be linearly movable between a standby position and a support position along a radial direction of the spin chuck 111C. The standby position is a position farther from the center of the spin chuck 111C than the support position. When the substrate W is loaded or unloaded on the spin chuck 111C, the chuck pin 113C may be positioned at the standby position, and the chuck pin 113C may be positioned at the support position when a process is performed for the substrate W. At the support position, the chuck pin 113C may be in contact with the circumference of the substrate W.

The substrate support unit 110 is provided with a separate elevation structure with the same/similar operation/structure as/to the elevation assembly 130 that ascends and descends the bowl assembly 120, so that it may be implemented to ascend and descend in the same/similar manner as/to the bowl assembly 120. In this way, various modifications may be made in the substrate support unit 110.

The substrate support unit 110, for example, the support shaft 114S may be provided with a first exhaust port 125A that is communicated with the outside to discharge the air.

The first exhaust port 125A is positioned on a circumferential surface of the spin chuck 111C so that gas is exhausted and a processing liquid does not pass through the first exhaust port 125A, and may extend upward.

However, although the first exhaust port 125A is directly provided on the circumferential surface of the spin chuck 111C in the present embodiment, it is not limited thereto, and the first exhaust port 125A may be provided with a separate cup/bowl around the spin chuck 111C, so that the airflow does not directly contact the spin chuck 111C. In this way, various modifications may be made in the first exhaust port 125A.

In addition, a guide module 126C is provided above the first exhaust port 125A to cover the first exhaust port 125A so that the processing liquid recovered to the bowl assembly 120 does not flow into the first exhaust port 125A.

For example, the guide module 126C may be provided to be inclined downward in an outward direction from the spin chuck 111C and/or the cup/bowl surrounding the spin chuck 111C, and may be provided above the first exhaust port 125A to block inflow of the processing liquid into the first exhaust port 125A but to flow the air thereinto.

The bowl assembly 120 may provide a space in which a substrate processing process is performed, and its upper portion may be open. The bowl assembly 120 may include a first bowl 121B, a second bowl 122B, a third bowl 123B, and/or a fourth bowl 124B. That is, the bowl assembly 120 may be provided to include 2 to 5 bowls.

Each of the bowls 121B, 122B, 123B and 124B may individually recover processing liquids having different types and/or acidities among processing liquids used in the process. The first bowl 121B may be provided in an annular ring or cup shape surrounding the substrate support unit 110, the second bowl 122B may be provided in an annular ring or cup shape surrounding the first bowl 121B, the third bowl 123B may be provided in an annular ring or cup shape surrounding the second bowl 122B, and the fourth bowl 124B may be provided in an annular ring or cup shape surrounding the third bowl 123B. That is, the respective bowls 121B, 122B, 123B and 124B may be provided to surround each other.

The first space 121S that is an inner space of the first bowl 121B, the second space 122S provided between the first bowl 121B and the second bowl 122B as an inner space of the second bowl 122B, the third space 123S provided between the second bowl 122B and the third bowl 123B as an inner space of the third bowl 123B, and the fourth space 124S provided between the third bowl 123B and the fourth bowl 124B as an inner space of the fourth bowl 124B may be provided as inlets through which the processing liquid flows into the first bowl 121B, the second bowl 122B, the third bowl 123B and the fourth bowl 124B, respectively.

The bowls 121B, 122B, 123B and 124B may be provided with a first discharge unit, a second discharge unit, a third discharge unit, and a fourth discharge unit, respectively, through which the processing liquid passes/discharged. The first discharge unit may discharge the processing liquid recovered to the first bowl 121B, and for example, when the first bowl 121B and/or a lower portion of the first bowl 121B are/is opened, the first discharge unit may be provided as a first discharge line 121L communicated with the lower portion of the first bowl 121B.

In addition, the second discharge unit may discharge the processing liquid recovered to the second bowl 122B, and may be provided as, for example, a second discharge line 122L connected to the second bowl 122B and/or the first bowl 121B (which may be a first barrier 121B1 in some embodiments).

The third discharge unit may discharge the processing liquid recovered to the third bowl 123B, and for example, may be provided as a third discharge line 123L connected to the third bowl 123B and/or the second bowl 122B (which may be a second barrier 122B2 in some embodiments).

In addition, the fourth discharge unit may discharge the processing liquid recovered to the fourth bowl 124B, and for example, when the fourth bowl 124B and/or a lower portion of the fourth bowl 124B are/is opened, the fourth discharge unit may be provided as a fourth discharge line 124L communicated with a bottom surface of the fourth bowl 124B.

Each of the discharge lines 121L, 122L, 123L and 124L may be provided with a valve capable of adjusting a flow rate of the processing liquid, a flow meter for measuring the flow rate of the processing liquid, and/or a filter for filtering particles. In addition, the discharge lines 121L, 122L, 123L and 124L may be provided as corrugated pipes and/or hoses so that their lengths increase or decrease in conjunction with the bowls 121B, 122B, 123B and 124B when the bowls 121B, 122B, 123B and 124B ascend and descend by the elevation assembly 130, but are not limited thereto, and various modifications may be made in the discharge lines within the range that conflicts with the present disclosure.

The processing liquid flowing through the first space 121S, the second space 122S, the third space 123S, and/or the fourth space 124S as the inlets provided to the plurality of bowls 121B, 122B, 123B and 124B may be discharged to a first drain tank 171T, a second drain tank 172T, a third drain tank 173T, a fourth drain tank 174T, and/or a recovery tank 161T, which are drain units 170 connected to the discharge lines 121L, 122L, 123L and 124L, through the discharge lines 121L, 122L, 123L and 124L.

That is, the processing liquid recovered to the bowls 121B, 122B, 123B and 124B may be disposed of and/or reused, and to this end, the discharge lines 121L, 122L, 123L and 124L may be connected to the first drain tank 171T, the second drain tank 172T, the third drain tank 173T, the fourth drain tank 174T, and/or the recovery tank 161T. At this time, the processing liquid supplied to the recovery tank 161T may be supplied to the processing liquid supply unit 150 so that it may be reused. That is, the recovery tank 161T may be connected to the processing liquid supply unit 150.

However, the processing liquid may not be recovered and only air flow may be formed in any one of the bowls 121B, 122B, 123B and 124B, and the bowls 121B, 122B, 123B and 124B, in which the processing liquid is not recovered and only air flow is formed, may be modified in various ways as the discharge lines 121L, 122L, 123L and 124L may be omitted.

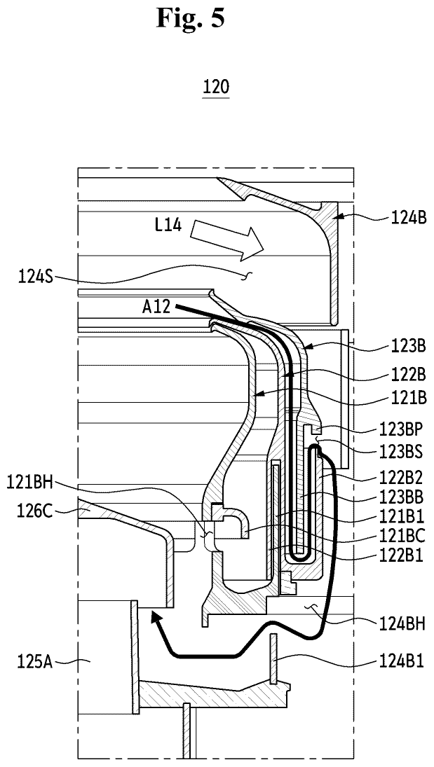

A shape of the bowl assembly 120 may be provided to facilitate separation of the processing liquid and/or formation of airflow in the processing space (e.g., around the bowls 121B, 122B, 123B and 124B). This will be described with reference to FIGS. 5 to 12.

The elevation assembly 130 may linearly move the bowl assembly 120 in the vertical direction. As the bowl assembly 120 is vertically moved, a relative height of the bowl assembly 120 with respect to the substrate support unit 110 may be changed.

The elevation assembly 130 may be provided with a first elevation unit 131, a second elevation unit 132, a third elevation unit 133, and/or a fourth elevation unit 134, which are/is individually connected to each of the bowls 121B, 122B, 123B and 124B so that each of the bowls 121B, 122B, 123B and 124B individually ascends or descends.

For example, the first elevation unit 131, the second elevation unit 132, the third elevation unit 133, and/or the fourth elevation unit 134 may be provided as a combination of a bracket, a moving shaft, a driver, a gear module, a motor, and/or an actuator, and the mechanism and/or structure of the known technology may be applied thereto.

When the first elevation unit 131, the second elevation unit 132, the third elevation unit 133, and/or the fourth elevation unit 134 are/is provided by passing through the housing of the process chamber 23 and/or the bowl assembly 120, ball bearings and/or O-rings are provided between the elevation assembly 130 and the bowl assembly 120 and/or the housing of the process chamber 23 so that ascending and descending of the elevation assembly 130 may be implemented to seal the housing of the process chamber 23 and/or the bowl assembly 120. In this way, various modifications may be made in the elevation assembly 130.

When the substrate processing process is performed, the elevation assembly 130 may adjust a height of the bowl assembly 120 so that the processing liquid may flow into the preset bowls 121B, 122B, 123B and 124B depending on the type of processing liquid supplied to the substrate W.

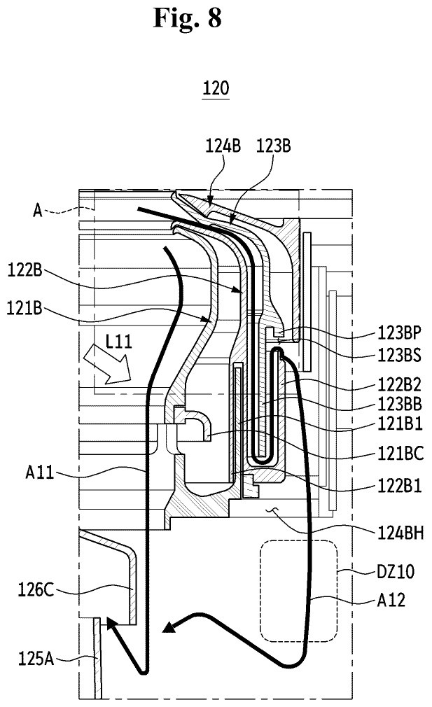

For example, while the substrate W is being processed with a first processing liquid L11 (see FIG. 8), the substrate W may be positioned at a height corresponding to the first space 121S, which is the inner space of the first bowl 121B.

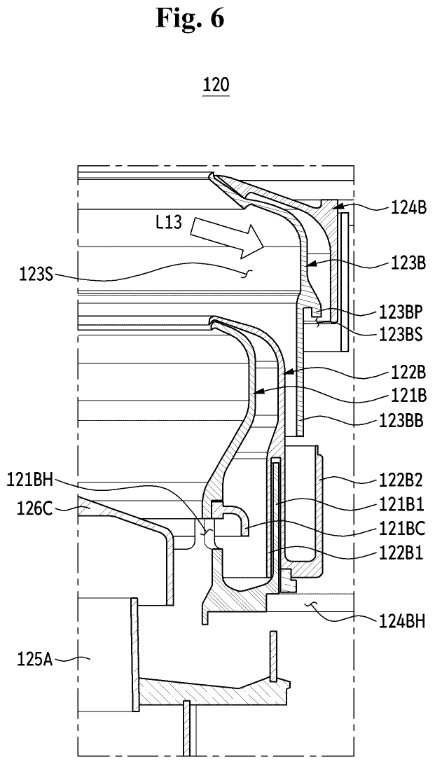

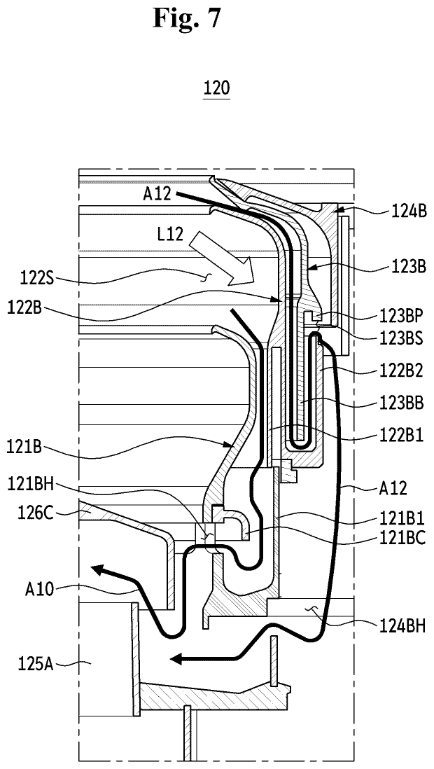

In addition, while the substrate W is being processed with a second processing liquid L12 (see FIG. 7), a third processing liquid L13 (see FIG. 6), and/or a fourth processing liquid L14 (see FIG. 5), the substrate W may be positioned at a height corresponding to the second space 122S, the third space 123S, and/or the fourth space 124S. In this case, the elevation assembly 130 adjusts only the level of the bowl assembly 120 so that the spin chuck 111C, the first space 121S, the second space 122S, the third space 123S, and/or the fourth space 124S may be positioned at a corresponding height, but the level of the bowl assembly 120 may be changed together with a level of the spin chuck 111C. In this way, the level of the bowl assembly 120 is not limited to one example.

Also, the elevation assembly 130 may descend the bowl assembly 120 so that the substrate support unit 110 is protruded toward an upper portion of the bowl assembly 120 when the substrate W is placed on the substrate support unit 110 or lifted from the substrate support unit 110.

The spray unit 140 may supply the processing liquid to the substrate W during the substrate processing process. The spray unit 140 may include a nozzle 141N and a driver 143M.

The nozzle 141N may be moved to a process position and a standby position by the driver 143M. The process position is a vertically upper region of the substrate support unit 110 so that the nozzle 141N may discharge the processing liquid onto the substrate W. The standby position is a position at which the nozzle 141N deviates from the outside of the vertically upper region of the substrate support unit 110.

The spray unit 140 may be provided as a plurality of spray units so that the processing liquid is supplied by being classified depending on its type. That is, the spray unit 140 may be provided in a structure in which different processing liquids are individually supplied so as not to be mixed, and this structure may be replaced with the known technology and thus its description will be omitted.

The processing liquid supply unit 150 may supply the processing liquid to the substrate W. The processing liquid supply unit 150 may be provided in the process chamber 23 together with the substrate processing apparatus 100, but may be provided in a control box for efficient layout and process. For example, the control box may be provided adjacent to the process chamber 23, and a plurality of valve systems for controlling the processing liquid may be provided.

Referring to FIGS. 3 and 4, the processing liquid supply unit 150 may include one or more supply tanks 151T and a supply line 151L.

For example, the supply tank 151T may be provided as two tanks, that is, a main tank and a sub tank. The main tank and the sub tank may supply the processing liquid to the substrate W individually.

That is, when the main tank supplies the processing liquid to the substrate W, and the processing liquid contained in the main tank is below a set level, the sub tank may supply the processing liquid to the substrate W. The main tank and the sub tank may have a structure in which they are connected to each other to circulate the processing liquid, or each of the main tank and the sub tank may have a structure in which the processing liquid is individually circulated, and a heat exchanger, a pump, and the like may be provided in a line for circulation.

In some embodiments, the processing liquid that has processed the substrate W may be recovered to the bowl assembly 120 and then drained or reused.

Referring to FIG. 3, the processing liquid may be recovered to the bowl assembly 120 (e.g., the second space 122S of the second bowl 122B) and then to the recovery tank 161T of a recovery assembly 160 via the discharge line (e.g., the second discharge line 122L), so that the processing liquid may be reused.

A recovery line 163L connected to the supply tank 151T is provided in the recovery tank 161T, so that the processing liquid recovered to the recovery tank 161T may be supplied to the supply tank 151T through the recovery line 163L. In this case, a valve and/or a pump may be supplied to the recovery line 163L so that the flow rate of the processing liquid may be adjusted.

The processing liquid stored in the supply tank 151T and/or the processing liquid supplied from the recovery tank 161T may be supplied to the substrate W through the supply line 151L connected to the spray unit 140.

In addition, referring to FIG. 4, the discharge line, for example, the second discharge line 122L may be connected to the recovery tank 161T, but may be branched as referenced by a reference number ‘172L’ and connected to the second drain tank 172T, so that the processing liquid at the initial time of the process of processing the substrate W is drained. This is because, at the initial time of the process of processing the substrate W, a concentration of contaminants (e.g., a film material of the substrate) that clean the substrate may be high, making it difficult to reuse or reduce efficiency.

For the drain of such processing liquid, the valve provided at the branch point of the second discharge line 122L may be adjusted so that the processing liquid may be drained to the second drain tank 172T. After the processing liquid is drained at the initial time of the process, a switching state of the valve may be changed, so that the processing liquid of FIG. 3 mentioned above may be recovered.

The supply tank 151T is illustrated as being implemented as the main tank and the sub tank with reference to FIGS. 3 and 4, but is not limited thereto.

As another example, although not shown in the drawings, the supply tank 151T includes a plurality of tanks, and may be implemented such that the processing liquid sequentially passes through the plurality of tanks. For example, the supply tank 151T includes three tanks, wherein one tank may be provided as a replenishment tank in which the processing liquid is replenished, another one tank may be provided as a buffer tank in which the processing liquid is supplied from the replenishment tank, and the other tank may be provided as a tank supplied with the processing liquid from the buffer tank, supplying the processing liquid to the substrate W. In this way, various modifications may be made in the supply tank. The processing liquid that has processed the substrate W may be recovered to the replenishment tank of the supply tank 151T, but the present disclosure is not limited thereto.

The processing liquid is illustrated as being recovered to the second space 122S of the second bowl 122B of the bowl assembly 120 and then to the recovery tank 161T of the recovery assembly 160 via the second discharge line 122L, but is not limited to thereto, and may be implemented so that the processing liquid recovered to another bowl may be recovered to the recovery tank 161T. In this way, various modifications may be made in the recovery of the processing liquid.

In other words, various modifications may be made in the recovery of the processing liquid so that the processing liquid recovered to a space provided in a structure in which the processing liquid is not mixed with other processing liquids may be recovered to the recovery tank 161T.

Hereinafter, an example in which the second processing liquid L12 easily flows into the second space 122S and the inflow of the other processing liquids is blocked to prevent/reduce contamination of the reused processing liquid and an airflow is formed in a dead zone DZ10 will be described with reference to the drawings. In particular, the airflow may be formed in the dead zone DZ10 even when the first processing liquid L11, the second processing liquid L12, and the fourth processing liquid L14 are recovered to the bowl assembly 120 to achieve a clean environment. This structure will be described with reference to the drawings.

However, redundant descriptions of the same elements performing the same function will be omitted.

The first processing liquid L11, the second processing liquid L12, the third processing liquid L13, and/or the fourth processing liquid L14 mentioned in the present embodiment may have different types and/or acidities as mentioned above.

For example, the first processing liquid L11 may be an acidic solution, the second processing liquid L12 may be a basic solution, and the third processing liquid L13 may be an acidic solution or a basic solution, which has an acidity different from that of the first processing liquid L11 or the second processing liquid L12. For example, the first processing liquid L11 may be a strongly acidic solution, the second processing liquid L12 may be a strongly basic solution, and the third processing liquid L13 may be a weakly acidic solution and/or a weakly basic solution. The fourth processing liquid L14 may be neutral and/or pure water.

In addition, in some embodiments, even though the first processing liquid L11 splashes on the third space 123S while an airflow is formed at the inlet of the third space 123S, the third processing liquid L13 recovered to the third space 123S may be set as a solution having low reactivity with the first processing liquid L11. Alternatively, the third processing liquid L13 may be neutral and/or pure water.

Also, the first processing liquid L11, the second processing liquid L12, the third processing liquid L13, and the fourth processing liquid L14 may be a chemical solution, in which other fluids such as an organic solvent (e.g., isopropyl alcohol (IPA)) are mixed, without being provided as any one solution, the first processing liquid L11 may be a basic solution, and the second processing liquid L12 may be an acidic solution. In this way, the processing liquid is not limited.

The processing liquid may be provided as a supercritical fluid and/or gas such as nitrogen gas. In other words, the processing liquid may be provided as various fluids for processing the substrate W, and the known technology may be applied thereto.

In other words, the type and/or acidity of the processing liquid mentioned in the present embodiment are/is only exemplary, and the present disclosure is not limited thereto.

Depending on the type, acidity, and/or reactivity, the processing liquid, that is, a plurality of processing liquids (e.g., the first processing liquid L11 and the second processing liquid L12) used individually in the process may generate salt during mixing to contaminate the surroundings through which the processing liquid passes, or may have a risk of heat generation, thereby being recovered separately from each other for each process. To this end, in the bowl assembly 120 of the present embodiment, the processing liquid may be recovered for each type in consideration of type, acidity and/or reactivity using the plurality of bowls 121B, 122B, 123B and 124B.

Hereinafter, the bowl assembly 120 will be described in detail with reference to the drawings.

Prior to the description, some embodiments mentioned in the present embodiment, for example, the first to fifth embodiments, are separately described for convenience of description and understanding, and the present disclosure is not limited to each embodiment, but another modified example may be made by intersection in the elements of the embodiments mentioned in the present disclosure and the known technology and/or combination of the embodiments.

FIG. 5 is a view illustrating a state that a fourth bowl of the substrate processing apparatus according to the first embodiment of the present disclosure is lifted, FIG. 6 is a view illustrating a state that a third bowl of the substrate processing apparatus according to the first embodiment of the present disclosure is lifted, and FIG. 7 is a view illustrating a state that a second bowl of the substrate processing apparatus according to the first embodiment of the present disclosure is lifted.

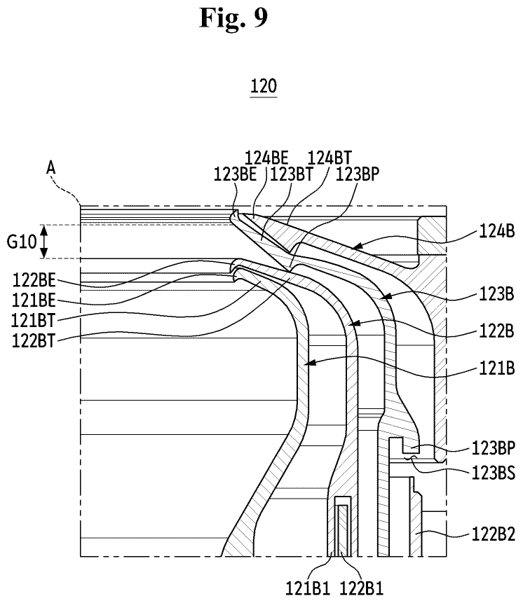

In addition, FIG. 8 is a view illustrating an airflow that flows along an inner side of a third bowl as a processing liquid is recovered to a first bowl of the substrate processing apparatus according to the first embodiment of the present disclosure, and FIG. 9 is a view illustrating a region A of FIG. 8.

Referring to FIGS. 5 to 9, the bowl assembly 120 of some embodiments has a structure for inflow of processing liquid, prevention of mixing of processing liquid, and/or flow of airflow, and shapes of upper walls 121BT, 122BT, 123BT and 124BT may be provided as various modified examples, or barriers 121B1, 122B2 and 124B1 may be provided.

First, the upper walls 121BT, 122BT, 123BT and 124BT for the structure for inflow of processing liquid, prevention of mixing of processing liquid, and/or flow of airflow will be described.

Referring to FIG. 9, the first bowl 121B, the second bowl 122B, the third bowl 123B and/or the fourth bowl 124B may be provided with upper walls 121BT, 122BT, 123BT and 124BT, respectively, which are provided to be inclined upward toward the substrate support unit 110.

The description will be based on that the upper walls 121BT, 122BT, 123BT and 124BT are provided as the first upper wall 121BT of the first bowl 121B, the second upper wall 122BT of the second bowl 122B, the third upper wall 123BT of the third bowl 123B, and the fourth upper wall 124BT of the fourth bowl 124B.

For convenience of description and understanding, edges of the upper walls 121BT, 122BT, 123BT and 124BT should be named as a first edge 121BE of the first bowl 121B, a second edge 122BE of the second bowl 122B, a third edge 123BE of the third bowl 123B, and a fourth edge 124BE of the fourth bowl 124B.

In some embodiments, one or more of the first upper wall 121BT, the second upper wall 122BT, the third upper wall 123BT, and the fourth upper wall 124BT may have different gradients, so that a gap between the upper walls 121BT, 122BT, 123BT and 124BT and the edges 121BE, 122BE, 123BE and 124BE, which are adjacent to one another, may be increased.

For example, the gradient of the second upper wall 122BT may be the same as or smaller than that of the first upper wall 121BT. That is, the second upper wall 122BT may be provided in a structure that is in contact with or retracted from the first upper wall 121BT.

Since the second upper wall 122BT may be provided in a structure in which the inlet of the second space 122S may be blocked depending on the level of the second bowl 122B with respect to the first bowl 121B, the inflow of the processing liquid other than the second processing liquid L12 may be blocked to prevent or reduce the mixing of other processing liquids with respect to the second processing liquid L12. Accordingly, when the second processing liquid L12 is reused, an effect of processing the substrate W by the second processing liquid L12 may be prevented from being deteriorated.

In addition, the second edge 122BE may be provided in a structure surrounding the first edge 121BE, for example, in a shape bent toward the first edge 121BE.

In some embodiments, the first edge 121BE may have a structure that is bent downward in the same/similar manner as/to the second edge 122BE while being surrounded by the second edge 122BE, but the present disclosure is not limited thereto. Unlike the second edge 122BE, the first edge 121BE may have a structure that is surrounded by the second edge 122BE without being bent. In this way, various modifications may be made in the first edge 121BE.

The third upper wall 123BT may be provided such that an inlet of the third space 123S is enlarged. The third upper wall 123BT may have an upper end portion including the third edge 123BE, which is bent upward to form a gradient different from that of the second upper wall 122BT. That is, the upper end portion, which is at least a portion of the third upper wall 123BT, may have a gradient greater than that of the second upper wall 122BT, so that a gap G10 between the second edge 122BE of the second upper wall 122BT and the third edge 123BE of the third upper wall 123BT may be enlarged. Accordingly, the third upper wall 123BT may be provided in a structure that is widened from the second upper wall 122BT.

Since the third upper wall 123BT has a structure that is widened from the second upper wall 122BT, an airflow may be easily formed/introduced into the third space 123S. When the airflow is discharged through the first exhaust port 125A while passing through the third space 123S of the third upper wall 123BT, the airflow may pass through the dead zone DZ10 (see FIG. 8), thereby preventing/reducing contaminants such as fume from being stagnated in the dead zone DZ10.

The third upper wall 123BT may be provided in various structures so that the airflow passes through the second upper wall 122BT even though the third upper wall 123BT is in contact with the second upper wall 122BT.

For example, the upper end portion of the third upper wall 123BT is bent to have a gradient greater than that of the second upper wall 122BT, and in some embodiments, a protrusion region 123BP may be formed in the bent region.

The protrusion region 123BP may be in contact with the second upper wall 122BT, and at this time, a lower end of the protrusion region 123BP has a wavy structure, so that a portion of the protrusion region 123BP may be in contact with an upper surface of the second upper wall 122BT and the other portion thereof may be provided to form a space with the second upper wall 122BT.

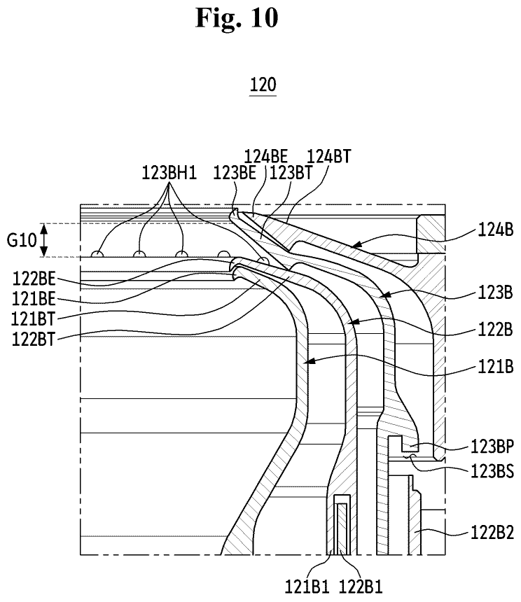

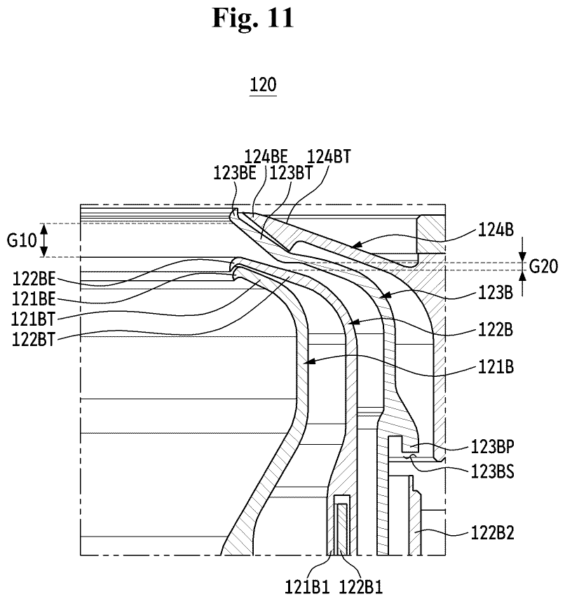

However, the present disclosure is not limited to the above example, and a wavy structure may be provided in the bent structure of the third upper wall 123BT while the protrusion region 123BP is not provided. Another modified example will be described with reference to FIGS. 10 and 11.

The third edge 123BE provided on the third upper wall 123BT may be bent in a direction different from that of the second edge 122BE. For example, the third edge 123BE may be bent upward to have a structure surrounding the fourth edge 124BE.

Therefore, since the inlet of the fourth bowl 124B may be blocked at the level of the third bowl 123B and the fourth bowl 124B, the processing liquid other than the fourth processing liquid L14 may be difficult to flow thereinto.

Since the fourth upper wall 124BT has a gradient the same as or smaller than that of the third upper wall 123BT, the fourth upper wall 124BT may be provided in a structure that is in contact with or retracted from the third upper wall 123BT in the same/similar manner as/to the second upper wall 122BT.

Referring to FIGS. 5 to 8, the bowl assembly 120 may be implemented so that the processing liquid is recovered or the inner air of the process chamber 23 flows

For example, the first bowl 121B may be provided with a first barrier 121B1 that is extended by being bent from the first upper wall 121BT in a direction of the second bowl 122B so that a space is formed between the second bowl 122B and the first bowl 121B. Accordingly, the second processing liquid L12 recovered to the second bowl 122B may be discharged through the second discharge line 122L that may be connected to a processing liquid accommodation space of the first barrier 121B1 in a state of being temporarily accommodated in the first barrier 121B1.

In some embodiments, the first bowl 121B has a first air hole 121BH penetrated at a position spaced apart from the bottom surface of the first barrier 121B1, so that, for example, an airflow A10 (see FIG. 7) forcibly formed by the fan filter unit FU10 may be discharged to the outside through the first exhaust port 125A by passing through the first air hole 121BH.

Since the first air hole 121BH is spaced apart from the bottom surface of the first barrier 121B1, the first air hole 121BH may be provided so that the second processing liquid L12 is recovered and at the same time the airflow flows without being blocked, but is not limited thereto. Various modifications may be made in the first air hole 121BH.

In addition, the first bowl 121B may include a first cover 121BC which is positioned above the first air hole 121BH in the first barrier 121B1 and is bent so that a gap is formed between the first air hole 121BH and the first cover 121BC, that is, bent so as not to block the first air hole 121BH. The first cover 121BC may block the second processing liquid L12 from flowing into the first air hole 121BH when the second processing liquid L12 is recovered.

The second bowl 122B may include a guide module 122B1 that is extended from a lower portion of the second upper wall 122BT and into which the first barrier 121B1 is inserted. The guide module 122B1 has a concave space formed from a lower portion toward an upper portion, so that it may ascend and descend while the first barrier 121B1 is being guided to the concave space of the guide module 122B when the level is changed depending on the ascending and descending of the first bowl 121B.

In addition, the second bowl 122B may include a second barrier 122B2 that is extended by being bent from the guide module 122B1 in a direction of the third bowl 123B so that a space is formed between the third bowl 123B and the second barrier 122B2.

The second barrier 122B2 may be bent in the same/similar manner as/to the first barrier 121B1 to form a space in which the processing liquid is temporarily accommodated, and may be provided so that a lower end 123BB of the third bowl 123B flows in and out of the space depending on ascending and descending.

That is, the lower end 123BB of the third bowl 123B may be positioned inside the second barrier 122B2. In addition, the third bowl 123B may include a rim 123BP that is protruded along a lower circumference of the third upper wall 123BT, that is, at a point to which the lower end 123BB is connected and forms a second gap 123BS with an upper end of the second barrier 122B2.

For example, the rim 123BP is provided with a structure such as a wavy shape, an embossing shape, and/or a cut groove, so that the airflow may pass through the rim 123BP even though the rim 123BP is in contact with the second barrier 122B2.

The fourth bowl 124B may have a structure in which a lower portion is opened, and thus a discharge hole 124BH may be formed to discharge the fourth processing liquid L14 or to form an airflow A12. In some embodiments, the fourth discharge line 124L may be communicated with a lower space of the discharge hole 124BH so that the fourth processing liquid L14 may be discharged through the discharge hole 124BH and the fourth discharge line 124L.

In addition, when the fourth processing liquid L14 is discharged through the discharge hole 124BH, the airflow A12 flows, but a fourth barrier 124B1 (see FIG. 5) may be provided below the discharge hole 124BH so that the fourth processing liquid L14 is separated from the first processing liquid L11. In this way, various structures for separation of the processing liquid and/or formation of the airflow may be provided.

In this bowl assembly 120, the level of each of the bowls 121B, 122B, 123B and 124B may be adjusted depending on the type of processing liquid, so that the processing liquid may be recovered separately.

Referring to FIG. 5, for discharging the fourth processing liquid L14, the fourth space 124S as an inlet may be exposed as the fourth bowl 124B ascends and descends. Accordingly, the fourth processing liquid L14 may be discharged through, for example, the fourth discharge line 124L after passing through the fourth space 124S.

At this time, since the third upper wall 123BT forms a structure widened from the second upper wall 122BT, as referenced by the reference number ‘A12’, the airflow A12 may be formed through the inlet of the third space 123S even in the process of discharging the fourth processing liquid L14, that is, in a state that the third bowl 123B does not ascend or descend.

Referring to FIG. 6, for discharging the third processing liquid L13, the third bowl 123B may ascend and descend so that the third space 123S as an inlet may be exposed. Accordingly, the third processing liquid L13 may be discharged through, for example, the third discharge line 123L after passing through the third space 123S.

Referring to FIG. 7, for discharging the second processing liquid L12, the second bowl 122B may ascend and descend so that the second space 122S as an inlet may be exposed. Accordingly, the second processing liquid L12 may be discharged through, for example, the second discharge line 122L after passing through the second space 122S.

At this time, since the third upper wall 123BT forms a structure widened from the second upper wall 122BT, as referenced by the reference number ‘A12’, the airflow A12 may be formed through the inlet of the third space 123S even in the process of discharging the second processing liquid L12, that is, in a state that the third bowl 123B and the fourth bowl 123B are close to and/or in contact with each other.

In addition, when the second space 122S is exposed and the second processing liquid L12 is not recovered as after the process of ascending and descending the second bowl 122B and/or the processing of the second processing liquid L12 is completed, an airflow A10 may be formed as the inner air of the process chamber 23 flows through the first air hole 121BH and the first exhaust port 125A by passing through the second space 122S.

However, since the first air hole 121BH is provided at a position spaced apart from the bottom surface of the first barrier 121B1, and a flow of the air may occur when the second processing liquid L12 is recovered, whereby the airflow A10 may be formed even when the second processing liquid L12 is recovered. In this way, the formation of the airflow A10 is not limited to any time.

Referring to FIG. 8, when the first processing liquid L12 is discharged, the first bowl 121B, the second bowl 122B, the third bowl 123B, and the fourth bowl 124B are close to and/or in contact with one another, and for example, a level of the substrate support unit 110 may be controlled to a relative level with respect to the bowl assembly 120 so that the first processing liquid L12 processed by the substrate support unit 110 does not flow into an inlet other than the first space 121S. For example, the level of the substrate support unit 110 may be between the lower end of the first upper wall 121BT of the first bowl 121B and the first air hole 121BH.

In addition, even though the first processing liquid L12 splashes, the second edge 122BE has a structure surrounding the first edge 121BE, so that the inlet of the second space 122S is closed, whereby the first processing liquid L12 may be blocked from flowing into the second space 122S.

At this time, not only the airflow such as the reference number ‘A11’ but also the airflow such as the reference number ‘A12’ is formed by the structure in which the third upper wall 123BT is widened from the second upper wall 122BT. Even in the process of discharging the first processing liquid L11, since the airflow A12 may be formed in the dead zone DZ10, fume may be easily discharged.

Hereinafter, another modified example of the present embodiment will be described with reference to FIGS. 10 to 13, and redundant descriptions of the same elements performing the same function will be omitted.

FIG. 10 is a view illustrating a bowl assembly of a substrate processing apparatus according to the second embodiment of the present disclosure. A difference from that described using FIGS. 2 to 9 will be mainly described with reference to FIG. 10.

Referring to FIG. 10, the third upper wall 123BT may have a concave groove 123BH1 through which the air passes. The concave groove 123BH1 may be provided in a semi-circular concave structure in the third upper wall 123BT. In this case, since the concave groove 123BH1 does not pass through the third upper wall 123BT, inflow of the fourth processing liquid that may flow into the upper surface of the third upper wall 123BT may be prevented.

This concave groove 123BH1 may be provided as an inlet of the airflow so that the airflow forcibly formed by the fan filter unit FU10 is always discharged to the outside, and various modified examples may be made in the concave groove 123BH1.

FIG. 11 is a view illustrating a bowl assembly of a substrate processing apparatus according to the third embodiment of the present disclosure. A difference from that described using FIGS. 2 to 10 will be mainly described with reference to FIG. 11.

Referring to FIG. 11, the third upper wall 123BT of the bowl assembly 120 may be provided in a structure in which a first gap G20 is formed between the second upper wall 122BT and the third upper wall 123BT. The third upper wall 123BT may have various modified examples as the protruding region 123BP of some embodiments may be provided in a smooth curved surface or in a deleted form.

Through the first gap G20, for example, the airflow forcibly formed by the fan filter unit FU10 may be provided to be discharged to the outside at all times and/or from time to time, so that fume may be discharged from time to time.

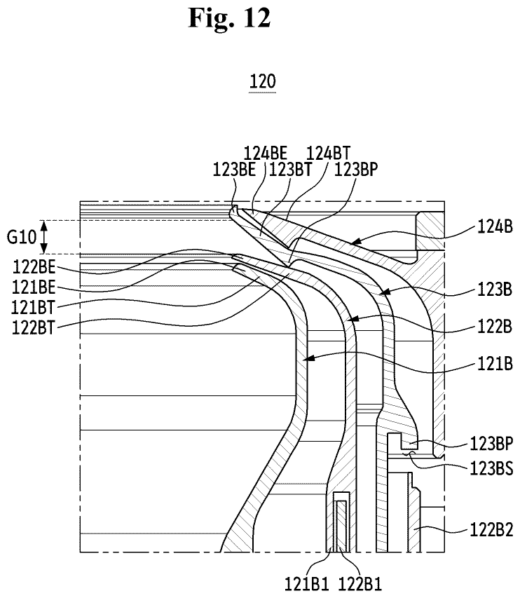

FIG. 12 is a view illustrating a bowl assembly of a substrate processing apparatus according to the fourth embodiment of the present disclosure. A difference from that described using FIGS. 2 to 11 will be mainly described with reference to FIG. 12.

It is illustrated that the first edge 121BE of the first upper wall 121BT and the second edge 122BE of the second upper wall 122BT of the above-described embodiment have a downwardly bent structure.

However, according to a modified example of some embodiments, the first edge 121BE and/or the second edge 122BE may be provided in an unbent structure. In this way, several modified examples may be made in the first edge 121BE and/or the second edge 122BE.

In addition, the second upper wall 122BT of some embodiments may be provided with a protrusion region of the same/similar shape as/to the protrusion region 123BP of the third upper wall 123BT. In this way, the embodiments mentioned in the present disclosure may be combined with each other, and one or more embodiments and/or known technologies may be combined to enable another embodiment.

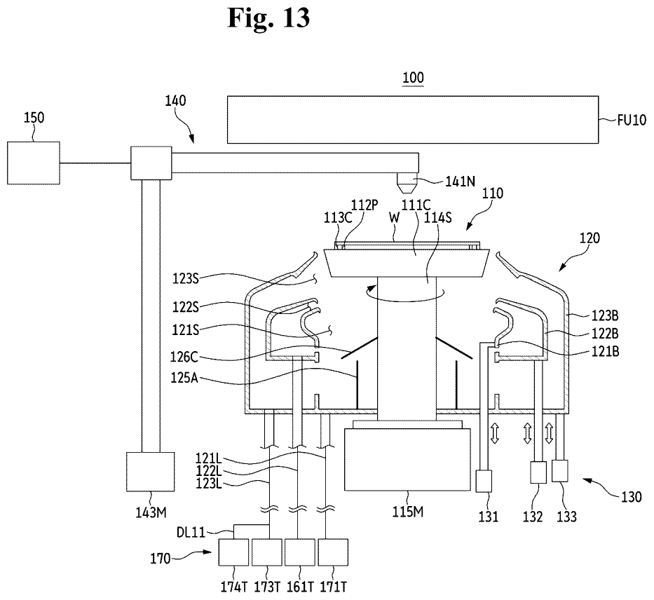

FIG. 13 is a view illustrating a substrate processing apparatus according to the fifth embodiment of the present disclosure. A difference from that described using FIGS. 2 to 12 will be mainly described with reference to FIG. 13.

Referring to FIG. 13, as mentioned above, since the bowl assembly 120 may be provided to include 2 to 5 bowls, the fourth bowl 124B may be omitted depending on modified examples, and the bowl assembly 120 may be provided to include the first bowl 121B, the second bowl 122B, and the third bowl 123B.

In addition, a branch line DL11 may be provided in any one of the first discharge unit, the second discharge unit, and the third discharge unit according to some embodiments. For example, the branch line DL11 may be provided to the third discharge line 123L provided as the third discharge unit, and a fourth drain tank 174T may be connected to the branch line DL11.

In this case, the processing liquid recovered to the third space 123S may be a third processing liquid L13 (see FIG. 6) and/or a fourth processing liquid L14 (see FIG. 5), and the third processing liquid L13 and the fourth processing liquid L14 may share a portion of the third discharge line 123L and thus be provided as processing liquids having no problem in mixing. For example, any one of the third processing liquid L13 and the fourth processing liquid L14 may be provided as pure water.

Although the embodiments of the present disclosure have been described with reference to the accompanying drawings, it will be apparent to those skilled in the art that the present disclosure can be fabricated in various forms without being limited to the above-described embodiments and can be embodied in other specific forms without departing from technical spirits and essential characteristics of the present disclosure. Thus, the above embodiments are to be considered in all respects as illustrative and not restrictive.

What is claimed is:

1. A bowl assembly comprising:
a first bowl provided to surround a substrate support unit supporting a substrate processed with a processing liquid;
a second bowl provided to surround the first bowl; and
a third bowl provided to surround the second bowl,
wherein each of the first bowl, the second bowl and the third bowl is provided with an upper wall that is provided to be inclined upward in a direction toward the substrate support unit,
the upper walls include a first upper wall of the first bowl, a second upper wall of the second bowl, and a third upper wall of the third bowl, and
each of the first upper wall, the second upper wall, and the third upper wall has an edge, and any one of the first upper wall, the second upper wall and the third upper wall has a structure that is widened toward its edge from a portion adjacent to its edge.

2. The bowl assembly of claim 1, wherein a gradient of the second upper wall is the same as or smaller than that of the first upper wall.

3. The bowl assembly of claim 1, wherein at least a portion of the third upper wall has a gradient greater than that of the second upper wall.

4. The bowl assembly of claim 3, wherein an upper end portion of the third upper wall, in which the edge is included, is bent upward to form a different gradient from the gradient of the second upper wall.

5. The bowl assembly of claim 4, wherein the third upper wall has a concave groove in the region where the upper end portion is bent, provided in a wave pattern, or has a first gap between the region where the upper end portion is bent and the second upper wall.

6. The bowl assembly of claim 4, further comprising a fourth bowl provided to surround the third bowl, wherein the fourth bowl has a fourth upper wall having a gradient the same as or smaller than that of a lower end portion of the third upper wall.

7. The bowl assembly of claim 1, wherein the edges include a first edge of the first bowl, a second edge of the second bowl, and a third edge of the third bowl, and the second edge is bent toward the first edge to surround the first edge.

8. The bowl assembly of claim 7, wherein the first edge is bent downward, and the third edge is bent upward.

9. The bowl assembly of claim 1, wherein the first bowl includes a first barrier that is extended by being bent from the first upper wall in a direction of the second bowl.

10. The bowl assembly of claim 9, wherein the first bowl includes:
a first air hole penetrated at a position spaced apart from a bottom surface of the first barrier; and
a first cover positioned above the first air hole in the first barrier, having a structure bent to form a gap with the first air hole.

11. The bowl assembly of claim 9, wherein the second bowl includes a guide module that is provided below the second upper wall and into which one end of the first barrier is inserted.

12. The bowl assembly of claim 11, wherein the second bowl includes a second barrier that is extended by being bent from the guide module in a direction of the third bowl.

13. The bowl assembly of claim 12, wherein a lower end portion of the third bowl is positioned inside the second barrier.

14. The bowl assembly of claim 13, wherein the third bowl includes a rim along a lower circumference of the third upper wall, the rim being provided with a second gap formed with an upper end of the second barrier.

15. A substrate processing apparatus comprising:
a substrate support unit supporting a substrate;
a bowl assembly of claim 1;
an elevation assembly ascending and descending the bowl assembly; and
a fan filter unit forming an airflow from an upper portion toward a lower portion of the substrate support unit,
wherein the elevation assembly includes:
a first elevation unit ascending and descending the first bowl;
a second elevation unit ascending and descending the second bowl; and
a third elevation unit ascending and descending the third bowl.

16. The substrate processing apparatus of claim 15, further comprising:
a first discharge unit implemented to discharge a processing liquid recovered from the first bowl;
a second discharge unit implemented to discharge a processing liquid recovered from the second bowl; and
a third discharge unit implemented to discharge a processing liquid recovered from the third bowl.

17. The substrate processing apparatus of claim 16, wherein any one of the first discharge unit, the second discharge unit and the third discharge unit is connected to a recovery tank to which a processing liquid is recovered, and
the recovery tank supplies the processing liquid to a processing liquid supply unit that supplies the processing liquid to the substrate support unit.

18. The substrate processing apparatus of claim 16, further comprising a drain unit in which the processing liquid discharged from the first discharge unit, the second discharge unit and the third discharge unit is drained,
wherein the drain unit includes:
a first drain tank connected to the first discharge unit;
a second drain tank connected to the second discharge unit; and
a third drain tank connected to the third discharge unit.

19. The substrate processing apparatus of claim 18, wherein any one of the first discharge unit, the second discharge unit and the third discharge unit is provided with a branch line and is further connected to a fourth drain tank.

20. A bowl assembly comprising:
a first bowl provided to surround a substrate support unit supporting a substrate processed with a processing liquid;
a second bowl provided to surround the first bowl; and
a third bowl provided to surround the second bowl,
wherein each of the first bowl, the second bowl and the third bowl is provided with an upper wall that is provided to be inclined upward in a direction toward the substrate support unit,
the upper walls include a first upper wall of the first bowl, a second upper wall of the second bowl, and a third upper wall of the third bowl,
the third upper wall has a gradient greater than that of the second upper wall so that it is widened from the second upper wall, and
an edge of the second upper wall is bent downward to surround an edge of the first upper wall.
